(19) United States
(12) Patent Application Publication
(10) Pub. No.: US 2006/0275041 A1
(43) Pub. Date: Dec. 7, 2006

(54) Optical transmitter and optical receiver

(75) Inventors: Mitsuhiro Kitaji, Kanagawa (JP); Yuji Ishizuka, Kanagawa (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION

(21) Appl. No.: 11/385,036

(22) Filed: Mar. 20, 2006

(30) Foreign Application Priority Data
Mar. 23, 2005 (JP) P.2005-084548

(51) Int. Cl. H04B 1/02; H04B 7/02; H03C 7/02; H04B 10/04; H04B 10/12

(52) U.S. Cl. 398/182

(57) ABSTRACT

In an optical transmitter provided with an LED that transmits a transmission bit stream as an optical signal by varying the luminance of visible light to be irradiated according to an input transmission bit stream, plural scramble data streams each having a different mark ratio are stored in a scramble data stream storage, and a light-control bit stream to which the mark ratio of the transmission bit stream is changed by performing a reversible bit operation on the transmission bit stream using a scramble data stream chosen among the stored scramble data streams. The light-control bit stream is then outputted to the LED.

### BACKGROUND OF THE INVENTION

The present invention relates to an optical transmitter and an optical receiver, and for example, to a technique for controlling a mark ratio of transmission data.

One type of visible light communications system for enabling communications by varying luminance of light emitting elements has the capability of controlling the luminance of the light emitting elements by controlling a mark ratio of a bit stream as communication data. The mark ratio is defined as a ratio of “1's” included in a bit stream. Because the light emitting element is ON when the bit exhibits “1” and OFF when the bit exhibits “0”, the luminance of the light emitting element can be controlled by controlling the mark ratio.

An example of the luminance control is described in JP-A-2004-72365. According to the PPM control described in JP-A-2004-72365, the luminance of the light emitting element is controlled without reducing the information volume included in a bit stream by replacing a transmission bit stream of a specific length with a replacement bit stream having a mark ratio that increases the luminance of the light emitting element. A concrete example of the PPM control will be described with reference to FIG. 10.

According to the PPM control shown in FIG. 10, a transmission bit stream X1 is divided to 2-bit specific-length bit streams X2, each of which is replaced with a replacement bit stream X3 having a mark ratio of 25% correspondingly to the type of bit configuration of each specific-length bit stream X2 (herein, “00”, “01”, “10”, and “11”). The mark ratio of the transmission bit stream is controlled to be 25% in this manner.

As has been described, the mark ratio of the transmission bit stream according to the PPM control is the mark ratio of the replacement bit streams X3. In other words, in order to obtain a bit stream having a target mark ratio by the PPM control, a replacement bit stream having this mark ratio is necessary. Assume that the replacement bit stream comprises four bits, then a replacement bit stream having a mark ratio of 25% can be generated by setting one bit in the four bits to “1”. However, it is impossible to generate a replacement bit stream having a mark ratio of 20%. Meanwhile, when the replacement bit stream comprises five bits, a replacement bit stream having a mark ratio of 20% can be generated by setting one bit in the five bits to “1”. In short, in the PPM control, the length of the replacement bit stream is determined according to the target mark ratio.

Redundant bit appending control is used as another technique for controlling the luminance of light emitting elements without reducing an information volume included in a bit stream. An example of redundant bit appending control will be described with reference to FIG. 11.

According to the redundant bit appending control shown in FIG. 11, a transmission bit stream X1 is divided in to 7-bit specific-length bit streams X4, and a redundant bit “0” is appended to each specific-length bit stream X4. This reduces the luminance of the light emitting elements. In this manner, the luminance of the light emitting elements is controlled without reducing an information volume included in a bit stream by the redundant bit appending processing.

According to the PPM control and the redundant bit appending control as described above, however, the redundancy of the bit stream is increased by controlling the mark ratio. On the contrary, fine-tuned adjustment (light control) of the luminance of the light emitting elements cannot be achieved with mark ratio control without some increase in redundancy.

### SUMMARY OF THE INVENTION

The invention was devised to solve the problems discussed above, and one of its objects is to provide an optical transmitter and an optical receiver that enable fine-tuned adjustment of the luminance of the light emitting elements using mark ratio control while suppressing an increase in the redundancy of the bit stream.

An optical transmitter according to one aspect of the invention includes: a light emitting section that emits visible light on which is superimposed an input transmission bit stream by varying luminance according to the transmission bit stream; a storage that stores plural operation bit streams each having a different mark ratio; a light-control bit stream generating section that generates a light-control bit stream to which the mark ratio of the transmission bit stream is changed by performing a reversible bit operation on the transmission bit stream using one of the operation bit streams stored in the storage; and a control section that controls light emission of the light emitting section according to the light-control bit stream generated in the light-control bit stream generating section.

Because the length of the bit stream does not change as a result of a bit operation, an increase in the redundancy of the bit stream caused by the mark ratio control can be suppressed by the invention. Further, by choosing an appropriate operation bit stream, fine-tuned adjustment of the luminance of the light emitting element is enabled.

The optical transmitter may be configured in such a manner that the storage stores an operation bit stream having a mark ratio c computed by:
c=(a−b)/(2a−1)
where a is a mark ratio of the transmission bit stream and b is a mark ratio of the light-control bit stream.

Also, the optical transmitter may further include a mark ratio fluctuating section that fluctuates the mark ratio of the transmission bit stream which is not changed by the bit operation in the light-control bit stream generating section, in advance.

According to the invention, even when there is a limit for a quantity of change of the mark ratio by the bit operation as in a case where the bit operation is an exclusive-OR operation, it is possible to perform the bit operation on the transmission bit stream so that the bit stream has a desired mark ratio in a more reliable manner.

The optical transmitter may be configured in such a manner that the light-control bit stream generating section performs an exclusive-OR operation on the transmission bit stream.

The exclusive-OR operation has the nature of a reversible operation such that when a given bit stream is exclusive-ORed twice using the same bit stream, the resulting bit stream is restored to the original bit stream. The exclusive-OR operation also has the nature of a mark ratio control operation. The mark ratio control operation is an operation where by performing an exclusive-OR operation on a first bit stream and a second bit stream bit by bit, then a bit stream having a mark ratio corresponding to the mark ratios of the first bit stream and the second bit stream is obtained. Further, the bit length of the bit stream obtained herein is the same as the bit length of the first bit stream. It is thus possible to use an exclusive-OR operation per bit as the bit operation.

Also, the optical transmitter may further include a light receiving section that receives ambient light, and an operation bit stream choosing section that chooses the operation bit stream having a mark ratio that cancels out a variation of the ambient light in response to an output of the light receiving section from the storage.

An optical receiver according to another aspect of the invention includes: a storage that stores plural operation bit streams each having a different mark ratio; a light receiving section that receives visible light whose luminance varies in response to a light-control bit stream generated by changing the mark ratio of a data bit stream by performing a reversible bit operation on the data bit stream; a light-control bit stream acquiring section that acquires the light-control bit stream from the visible light received at the light receiving section; a specifying information acquiring section that acquires operation bit stream specifying information that specifies the operation bit stream used in the reversible bit operation from the visible light received at the light receiving section; and a data bit stream regenerating section that regenerates the data bit stream by choosing one operation bit stream from the storage according to the operation bit stream specifying information acquired by the specifying information acquiring section and by performing the reversible bit operation on the light-control bit stream using the chosen operation bit stream.

### BRIEF DESCRIPTION OF THE DRAWINGS

FIG. 1 is a view showing the system configuration of a visible light communications system according to one embodiment of the invention;

FIG. 2 is a view showing a relationship between output of a light emitting element and time according to one embodiment of the invention;

FIG. 3 is a view showing a change of a moving average of an output of the light emitting element with time according to one embodiment of the invention;

FIG. 4 is a functional block diagram of an optical transmitter according to one embodiment of the invention;

FIG. 5 is a view showing a scramble data stream table according to one embodiment of the invention;

FIG. 6 is a view used to describe an exclusive-OR operation according to one embodiment of the invention;

FIG. 7A is a view showing a change of luminance with time for an output of a fluorescent tube and an output of the light emitting element according to one embodiment of the invention;

FIG. 7B is a view showing a change of luminance with time for light in which an output of the fluorescent tube and an output of the light emitting element are superimposed according to one embodiment of the invention;

FIG. 8 is a view showing transmission data according to one embodiment of the invention;

FIG. 9 is a functional block diagram of an optical receiver according to one embodiment of the invention;

FIG. 10 is a view used to describe the PPM control according to the background art of the invention; and

FIG. 11 is a view used to describe the redundant bit appending control according to the background art of the invention.

### DESCRIPTION OF THE PREFERRED EMBODIMENTS

One embodiment of the invention will be described with reference to the drawings.

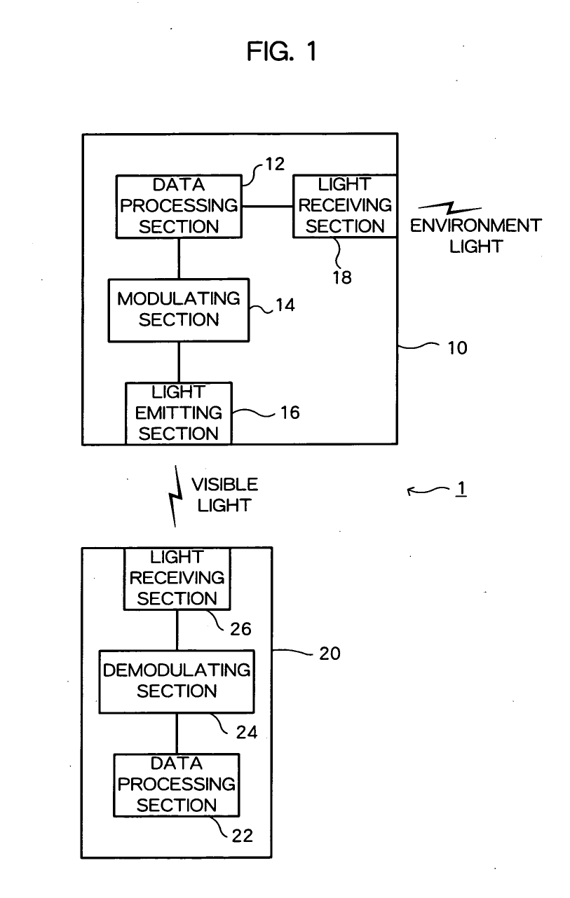

FIG. 1 is a view showing the system configuration of a visible light communications system 1 according to one embodiment. As is shown in the drawing, the visible light communications system 1 of this embodiment includes at least one optical transmitter 10 and at least one optical receiver 20, and one-way visible light communications using visible light as a communication medium are enabled by transmitting a communication signal from the optical transmitter 10 to the optical receiver 20.

The optical transmitter 10 is a visible light communications device comprising a data processing section 12, a modulating section 14, a light emitting section 16, and a light receiving section 18. The light emitting section 16 comprises light emitting elements. Normally, a large number of light emitting elements are arrayed in the light emitting section 16. The optical transmitter 10 makes communications with the optical receiver 20 with the use of emission of light by the light emitting elements included in the light emitting section 16.

The data processing section 12 outputs transmission data to the modulating section 14 as a communication signal to be transmitted to the optical receiver 20 through visible light communications. The modulating section 14 acquires a bit stream from the light emitting section 16 as a signal to be transmitted according to a communication signal inputted from the data processing section 12. The modulating section 14 then outputs the bit stream thus acquired to the light emitting section 16.

The light emitting section 16 changes the luminance of each light emitting element according to the bit stream inputted from the modulating section 14. Hereinafter, descriptions will be given on the assumption that the light emitting section 16 changes the luminance by causing the light emitting elements to blink according to the bit stream inputted from the modulating section 14. It should be noted, however, that the change of the luminance includes not only the blinking of the light emitting elements, but also, for example, a change in intensity of luminance, and a change of illuminance by shielding or unshielding light.

It is preferable to use light emitting elements capable of emitting light, such as an LED (Light Emitting Diode) and a thin-film transistor, as the light emitting elements used herein. The light emitting elements are normally used for communications as well as for illumination and displays. In other words, the visible light communications system 1 is configured in such a manner that the light emitting elements used for illumination and displays are used also for communications.

The light receiving section 18 includes light receiving elements, such as light sensors, and acquires illuminance of illumination light (for example, fluorescent light) as environment light (ambient light) of the optical transmitter 10. The light receiving section 18 outputs the illuminance thus acquired to the data processing section 12 as illuminance data.

The optical receiver 20 is a visible light communications device comprising a data processing section 22, a demodulating section 24, and a light receiving section 26. The light receiving section 26 comprises light receiving elements, such as light sensors.

The light receiving section 26 acquires a variation of the luminance of the light emitting elements in the light emitting section 16 by means of the light receiving elements, and converts the variation to a bit stream, which is outputted to the demodulating section 24. The demodulating section 24 acquires a communication signal on the basis of the input bit stream by specific processing described below, and outputs the communication signal to the data processing section 22. The data processing section 22 then performs specific processing according to the input communication signal.

The mark ratio will now be described. The mark ratio is a value indicating a ratio of “1's” included in a bit stream. The light emitting section 16 acquires a bit stream inputted from the modulating section 14 and comprising plural bits each exhibiting a value of either “0” or “1”. The light emitting section 16 then acquires bits included in the bit stream successively, and controls the light emitting elements successively to blink according to the bits thus acquired. The mark ratio therefore influences a ratio of blinking of the light emitting elements in the light emitting section 16. In other words, the ON output ratio (a ratio of outputs being “ON”) of the light emitting elements in the light emitting section 16 varies with a difference of the mark ratio.

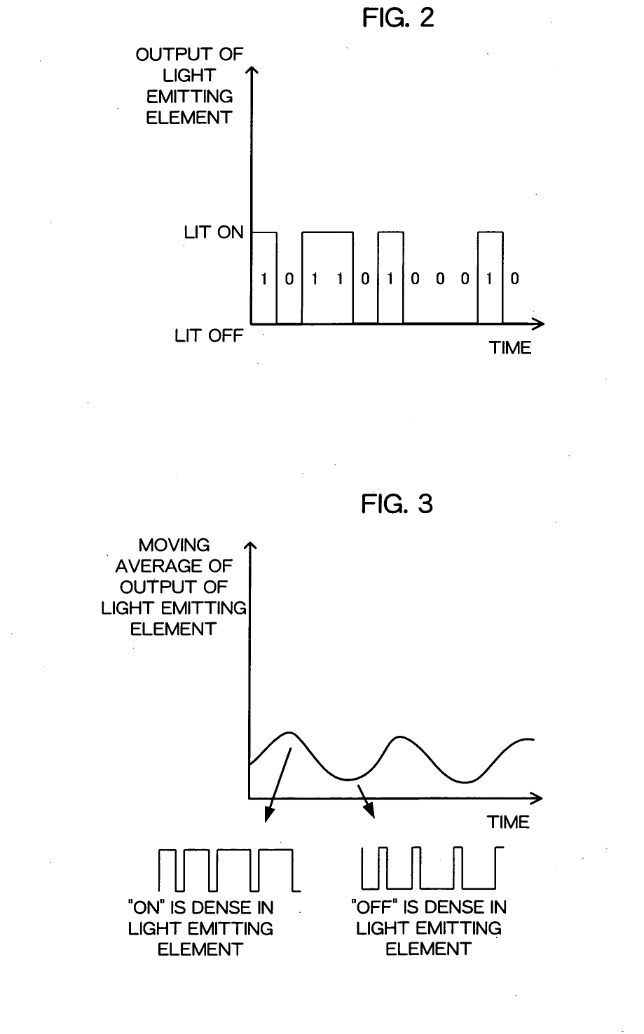

A concrete example of the blinking of the light emitting elements in the light emitting section 16 is shown in FIG. 2. FIG. 2 is a view showing a relationship between output of the light emitting element and time. Also, numbers, “0” and “1”, represent the bits that are acquired successively. As is shown in the drawing, when a bit exhibiting “1” is acquired, the optical transmitter 10 sets an output of the light emitting element to an “ON” state (lit ON state), and when a bit exhibiting “0” is acquired, it sets an output of the light emitting element to an “OFF” state (lit OFF state).

Influence of the mark ratio on the luminance of the light emitting element will now be described.

FIG. 3 is a view showing a change of a moving average of an output of the light emitting element with time. The moving average of an output of the light emitting element is computed sequentially by assigning “1” and “0” to “ON” and “OFF”, respectively. In short, the moving average of an output of the light emitting element is a numerical value that indicates an ON output ratio within a specific time. As is shown in the drawing, the moving average of an output of the light emitting element in the light transmitter 10 varies with time. To be more specific, it increases as the ON output ratio of the light emitting element within a specific time becomes higher.

The luminance of the light emitting element is expressed by the moving average of an output of the light emitting element. That is to say, the luminance varies in response to the ON output ratio within a specific time. Further, the luminance of the light emitting element varies in response to the mark ratio of a bit stream transmitted to the light emitting element within a specific time. The luminance is therefore increased (the light emitting element becomes brighter) as the mark ratio of the transmitted bit stream becomes higher. Conversely, the luminance is decreased (the light emitting element becomes darker) as the mark ratio of the transmitted bit stream becomes lower. As has been described, the mark ratio of the bit stream transmitted to the light emitting element influences the luminance of light emitted from the light emitting element.

With the visible light communications system 1 according to this embodiment, the transmission bit stream is not outputted to the light emitting section 16 intact, and instead, a light-control bit stream generated by converting the mark ratio of the transmission bit stream to an arbitrary mark ratio is outputted to the light emitting section 16. This configuration makes it possible to cancel out the fluctuation of environment light received at the light receiving section 18 by the light emitted from the light emitting elements in the light emitting section 16.

The configurations and the functions of the optical transmitter 10 and the optical receiver 20 according to this embodiment will now be described in detail.

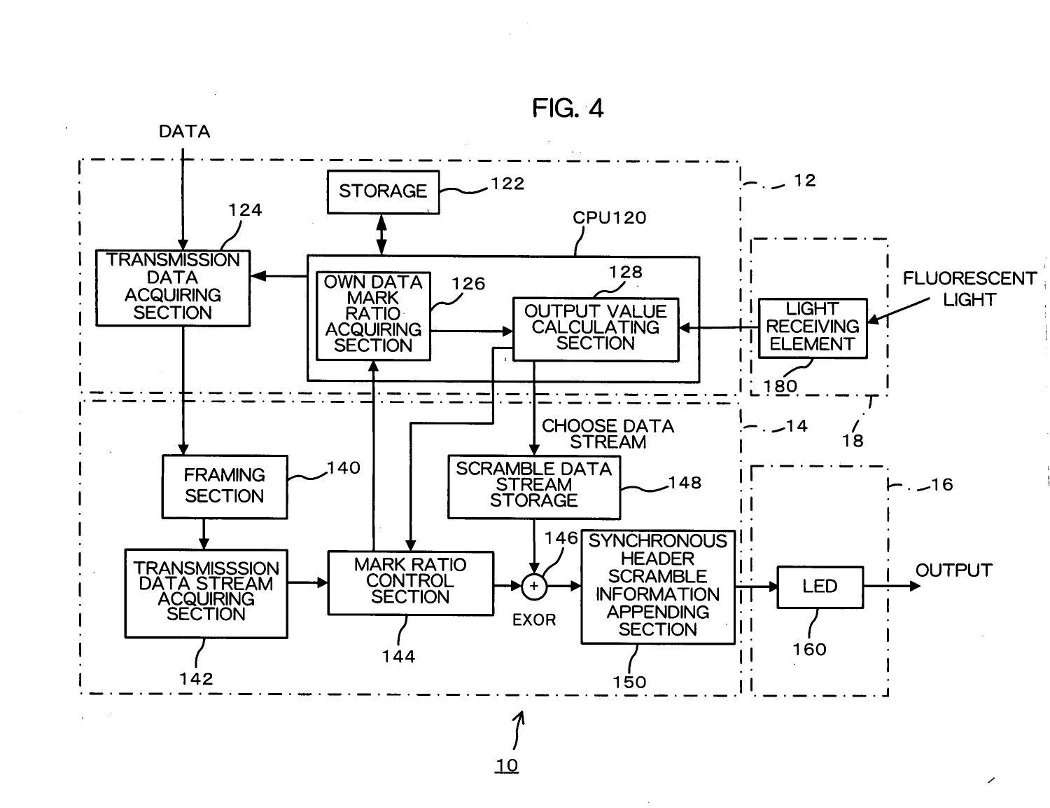

FIG. 4 is a functional block diagram showing the functional blocks of the optical transmitter 10 according to this embodiment. As is shown in the drawing, the optical transmitter 10 includes a CPU 120, a storage 122, and a transmission data acquiring section 124 in the data processing section 12. Also, it includes an own data mark ratio acquiring section 126 and an output value calculating section 128 in the CPU 120. In addition, the optical transmitter 10 includes a framing section 140, a transmission data stream acquiring section 142, a mark ratio control section 144, an EXOR unit 146, a scramble data stream storage 148, and a synchronous header scramble information appending section 150 in the modulating section 14. It further includes light emitting elements 160 in the light emitting section 16, and light receiving elements 180 in the light receiving section 18.

The function of each section included in the data processing section 12 will be described first.

The CPU 120 is a processing unit to execute a program stored in the storage 122, and it not only controls the respective sections in the optical transmitter 10, but also performs processing on transmission data. The storage 122 stores a program to perform this embodiment. The storage 122 also operates as a work memory for the CPU 120.

The transmission data acquiring section 124 acquires transmission data (user data) as transmission data from an unillustrated communications network. The transmission data acquiring section 124 then outputs the transmission data to the modulating section 14 under the control of the CPU 120.

The own data mark ratio acquiring section 126 acquires the mark ratio of the transmission bit stream after the mark ratio is changed in the mark ratio control section 144 as will be described below. The own data mark ratio acquiring section 126 then outputs the mark ratio to the output value calculating section 128.

The output value calculating section 128 acquires luminance of fluorescent light as environment light received at the light receiving elements 180. The output value calculating section 128 determines a target mark ratio as the target value of the mark ratio of the transmission data on the basis of the mark ratio of the transmission bit stream and the luminance of environment light. Further, the output value calculating section 128 determines the mark ratio of the scramble data stream described below on the basis of the mark ratio of the transmission bit stream and the target mark ratio. The mark ratio of the scramble data stream thus takes a value corresponding to both the target mark ratio and the mark ratio of the transmission bit stream. The output value calculating section 128 then outputs the target mark ratio to the mark ratio control section 144 and outputs the mark ratio of the scramble data stream to the scramble data stream storage 148.

The output value calculating section 128 acquires the luminance of fluorescent light in order to cancel out the fluctuation of luminance of the fluorescent light (such a fluctuation of luminance is referred to as flicker noise in the case of fluorescent light) by the processing described below. The output value calculating section 128 therefore performs the target mark ratio determination processing at a speed at which the flicker noise can be identified in a satisfactory manner. Also, the light receiving elements 180 acquire the luminance of fluorescent light at a speed at which the flicker noise can be identified in a satisfactory manner and output the luminance to the output value calculating section 128 in the same manner as above.

The scramble data stream mark ratio determination processing to determine the mark ratio of the scramble data stream will now be described in detail. As will be described below, descriptions will be given on the assumption that an exclusive-OR operation using the scramble data stream is performed on the transmission bit stream. Let A be the mark ratio of the transmission bit stream, B be the target mark ratio (the mark ratio of the light-control bit stream), and C be the mark ratio of the scramble data stream (mark ratio of the operation bit stream), then a relationship between these mark ratios can be expressed by Equation (1) below:
B={(1−A)C}+{A(1−C)} (1)

Equation (1) above indicates that the exclusive-ORed bit exhibits “1” in a case where the bit in the transmission bit stream exhibits “0” and the bit in the scramble data stream exhibits “1”, or in a case where the bit in the transmission bit stream exhibits “1” and the bit in the scramble data stream exhibits “0”. Equation (1) above can be re-written as Equation (2) below:
C=(A−B)/(2A−1) (2)

The output value calculating section 128 is thus able to determine the mark ratio C of the scramble data stream. The scramble data stream having the mark ratio C (or approximately the mark ratio C) determined herein has been previously stored in the scramble data stream storage 148.

The function of each section in the modulating section 14 will now be described.

The framing section 140 makes frames from the transmission data successively inputted from the transmission data acquiring section 124, and outputs the frames successively to the transmission data stream acquiring section 142. To be more concrete, the framing section 140 divides the transmission data by a specific length, and appends a necessary header to each, thereby making frames one by one. The framing section 140 then outputs the frames thus acquired successively to the transmission data stream acquiring section 142.

The transmission data stream acquiring section 142 acquires the transmission data made in the form of the frames in the framing section 140 successively as bit streams comprising bits exhibiting “0” or “1”. The transmission data stream acquiring section 142 then outputs the bit streams thus acquired successively to the mark ratio control section 144.

The mark ratio control section 144 performs specific mark ratio changing processing on the bit streams of a specific length inputted from the transmission data stream acquiring section 142. The mark ratio control section 144 performs this processing, for example, using PPM (Pulse Position Modulation) control or the redundant bit appending control described above. For example, in the case of PPM control, the mark ratio control section 144 fluctuates (increases or decreases) the mark ratio of the transmission bit stream by replacing the transmission bit stream of a specific length with the replacement bit stream having a specific mark ratio. The replacement bit stream is longer than the transmission bit stream of a specific length. Hence, according to the PPM control, the bit stream is outputted to the EXOR unit 146 as a specific-length bit stream of a length longer than the inputted length. Likewise, in the case of the redundant bit appending control, the mark ratio control section 144 outputs the bit stream to the EXOR unit 146 as a specific-length bit stream of a length longer than the inputted length. Hereinafter, descriptions will be given on the assumption that the mark ratio control section 144 performs the mark ratio changing processing by performing the redundant bit appending control on the bit stream.

The mark ratio control section 144 changes the mark ratio of the transmission bit stream to be the mark ratio corresponding to the target mark ratio inputted from the output value calculating section 128. In short, as will be described below, there is a limit for a quantity of change of the mark ratio by the exclusive-OR operation. The mark ratio control section 144 therefore obtains a light-control bit stream having the target mark ratio in a more reliable manner by changing the mark ratio of the transmission bit stream to be the mark ratio corresponding to the target mark ratio.

The scramble data stream storage 148 has stored scramble data streams. The scramble data stream is an operation bit stream having a specific mark ratio. The scramble data stream storage 148 chooses a scramble data stream corresponding to the mark ratio inputted from the output value calculating section 128 from the scramble data streams stored therein, and outputs the scramble data stream thus chosen to the EXOR unit 146.

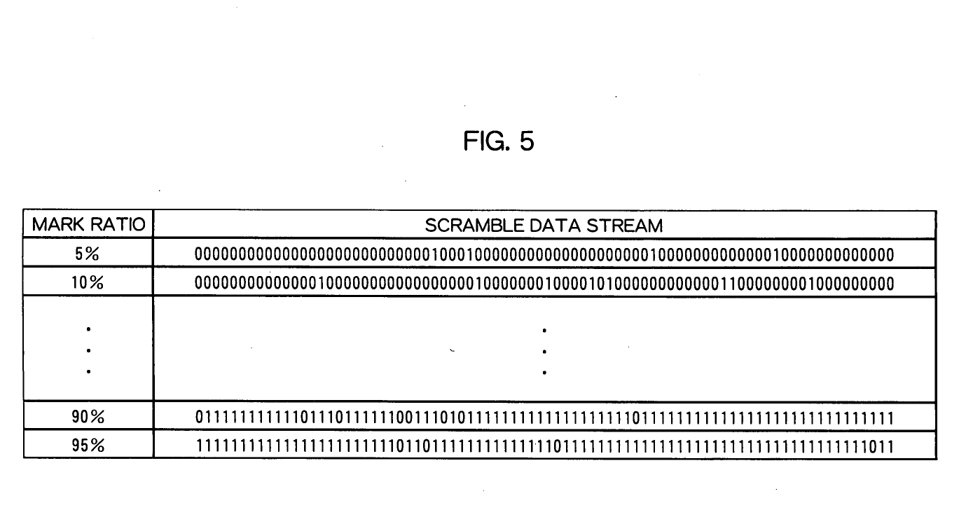

An example of a scramble data stream table stored in the scramble data stream storage 148 is shown in FIG. 5. Plural scramble data streams each having a different mark ratio are stored in the scramble data stream table shown in the drawing. In this table, the length of the scramble data streams is 80 bits, and the length is preferably the length of a bit stream after the mark ratio is changed in the mark ratio control section 144.

The EXOR unit 146 performs an exclusive-OR operation on the transmission bit stream outputted from the mark ratio control section 144 using the scramble data stream outputted from the scramble data stream storage 148. The EXOR unit 146 then outputs the light-control bit stream outputted as a result of the exclusive-OR operation to the synchronous header scramble information appending section 150.

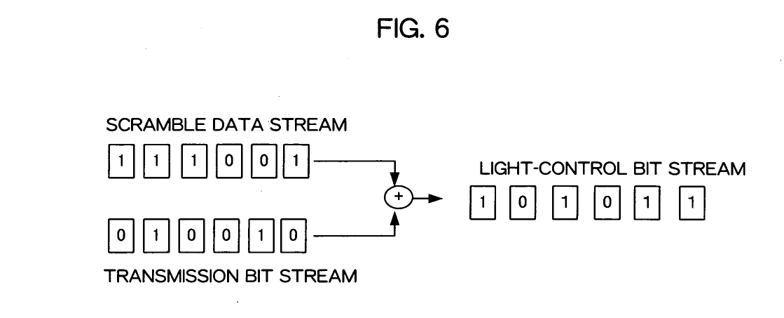

The processing in the EXOR unit 146 will be described with reference to FIG. 6. FIG. 6 is a view schematically showing an exclusive-OR operation in the EXOR unit 146. As is shown in the drawing, the input scramble data stream and the input transmission bit stream are exclusive-ORed bit by bit. The light-control bit stream of the same length as the transmission bit stream is outputted as the result of the operation. The mark ratio of the light-control bit stream outputted in this instance is almost the target mark ratio. Although the mark ratio of the light-control bit stream outputted as the result of the exclusive-OR operation is not necessarily the exact target mark ratio, it is almost the target ratio. In other words, because a change of the mark ratio by the exclusive-OR operation is probabilistic, the resulting mark ratio is not necessarily the exact mark ratio. However, the resulting mark ratio will always be almost the target mark ratio.

In addition, there is a limit for a quantity of change of the mark ratio by an exclusive-OR operation. In other words, the mark ratio of the light-control bit stream obtained by the exclusive-OR operation satisfies Equation (3) below:
|50%−mark ratio of input transmission bit stream|≧|50%−mark ratio of light-control bit stream obtained by exclusive-OR operation| (3)

The mark ratio of the light-control bit stream obtained by the exclusive-OR operation therefore takes approximately a value equal to or larger than 50%−|50%−the mark ratio of the input transmission bit stream | and equal to or smaller than 50%+|50%−the mark ratio of the input transmission bit stream|.

In this embodiment, the mark ratio control section 144 changes the mark ratio of the transmission bit stream to be the mark ratio corresponding to the target mark ratio. Hence, because the mark ratio of the transmission bit stream can be changed in such manner that the target mark ratio falls within the limit, an arbitrary target mark ratio can be obtained by an exclusive-OR operation.

Another operation may be used instead of an exclusive-OR operation. To be more specific, any operation can be used as long as it is a reversible operation capable of obtaining a bit stream, which is a bit stream having the mark ratio corresponding to the mark ratios of a first bit stream and a second bit stream and having the same bit length as the first bit stream, by performing the operation using the second bit stream on the first bit stream. For example, multiplication of bit streams, such as multiplications of the transmission bit stream and a PN sequence in the DS-CDMA (Direct Sequence-Code Division Multiple Access) can be used as the operation in this embodiment because the multiplications have the foregoing characteristics. In addition, some operations have no limit as described above, and the need to provide the mark ratio control section 144 to obtain an arbitrary mark ratio can be eliminated in such a case.

The multiplications of the transmission bit stream and the PN sequence in the DS-CDMA will be described more concretely. In the DS-CDMA, for all the bits included in the transmission bit stream and the PN sequence, a bit exhibiting “1” is changed to “−1” and a bit exhibiting “0” is changed to “1” before multiplications. Then, multiplying “−1” by “−1” yields “1”, multiplying “−1” by “1” yields “−1”, and multiplying “1” by “1” yields “1”. These results of the multiplications are equivalent to the result of the exclusive-OR operation: exclusive-ORing “1” and “1” yields “0”, exclusive-ORing “1” and “0” yields “1”, and exclusive-ORing “0” and “0” yields “0”. By replacing a combination of “0” and “1” with a combination of “1” and “−1” beforehand in this manner, it is possible to achieve an operation equivalent to an exclusive-OR operation by multiplications.

Also, as has been described, the output value calculating section 128 determines the target mark ratio, which is the target value of the mark ratio of the transmission data, on the basis of the mark ratio of the transmission bit stream and the luminance of environment light. Also, as has been described, the luminance of the light emitting element varies with the mark ratio of the bit stream transmitted to the light emitting element. The output value calculating section 128 therefore determines the target mark ratio so that the light emitting element has luminance such that it can cancel out the flicker noise of environment light. It is thus possible to cancel out the flicker noise using light emitted by the light emitting elements 160.

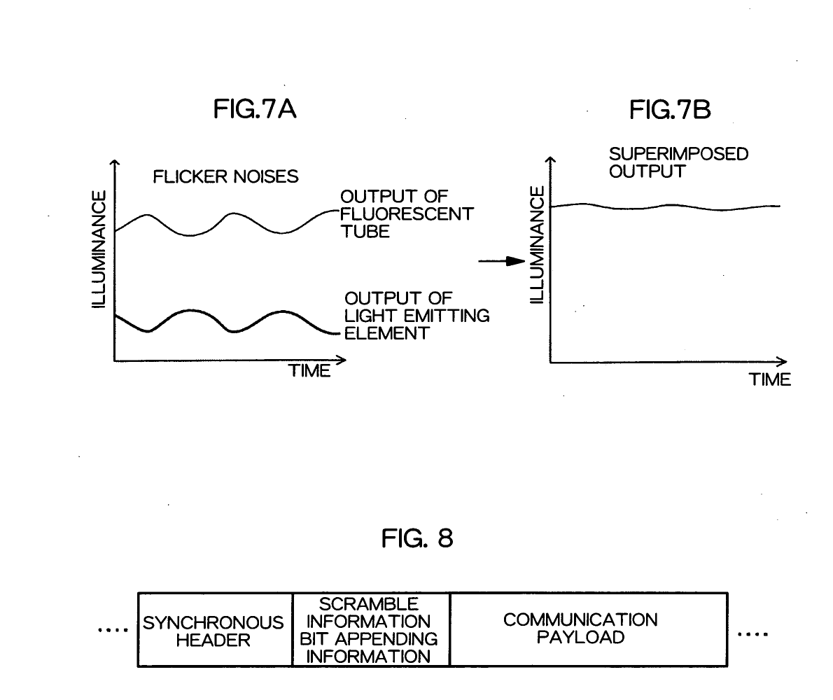

A concrete example will be described with reference to FIGS. 7A and 7B. FIG. 7A is a graph showing changes of luminance with time for an output of a fluorescent tube and an output of the light emitting element. As is shown in FIG. 7A, an output of the fluorescent tube varies at a frequency of 50 Hz or 60 Hz (flicker noise). In this embodiment, an output of the light emitting element is varied to cancel out such a variation. In other words, the output of the light emitting element is also varied by varying the target mark ratio in response to the flicker noise. When these two kinds of light are superimposed, as is shown in FIG. 7B, the flicker noise is cancelled out and an optical output becomes almost flat. In this embodiment, the flicker noise of environment light is cancelled out in this manner.

The processing in the synchronous header scramble information appending section 150 will now be described. The synchronous header scramble information appending section 150 first acquires the scramble information that specifies the scramble data stream used in the EXOR unit 146 (the operation bit stream specifying information that specifies the operation bit stream used in the EXOR unit 146). Also, the synchronous header scramble information appending section 150 acquires bit appending information indicating a redundant bit appended in the mark ratio control section 144. Further, the synchronous header scramble information appending section 150 acquires a synchronous header for synchronization in the optical receiver 20. The synchronous header scramble information appending section 150 then combines all these data and the light-control bit stream outputted from the EXOR unit 146 into single transmission data, and outputs the bit stream as the transmission data to the light emitting section 16.

FIG. 8 shows an example of the transmission data. As is shown in the drawing, the transmission data is a bit stream including the synchronous header, the scramble information/bit appending information, and a communication payload as the bit stream outputted from the EXOR unit 146. The synchronous header scramble information appending section 150 generates transmission data successively for the light-control bit streams outputted successively from the EXOR unit 146, and outputs the transmission data to the light emitting section 16.

The light emitting section 16 transmits the transmission data by causing the light emitting elements 160 to blink according to the input bit streams.

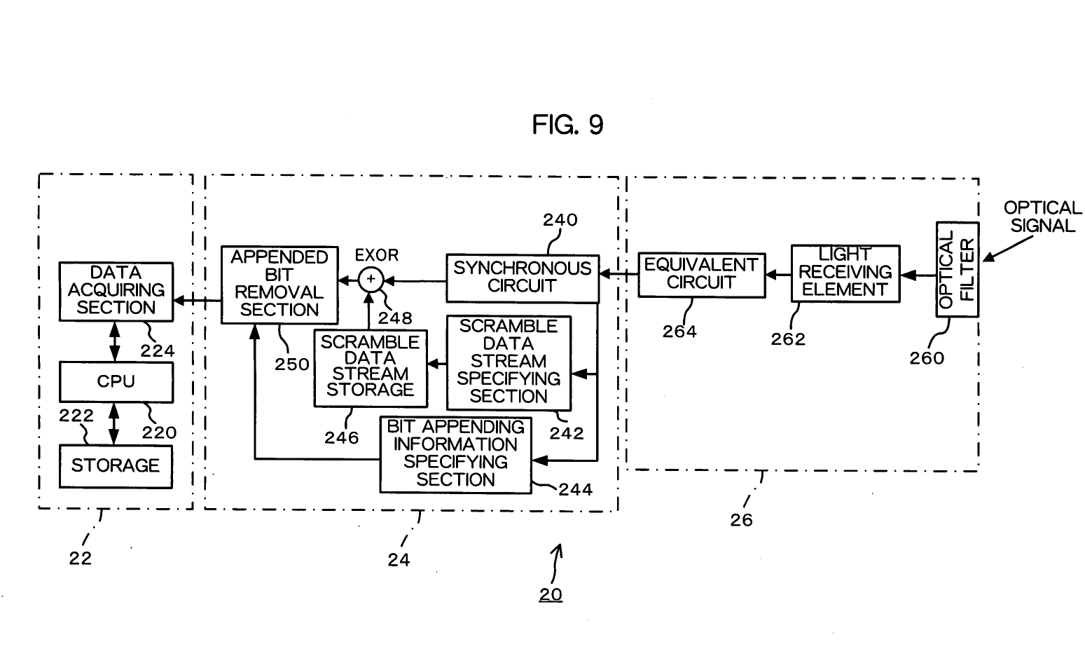

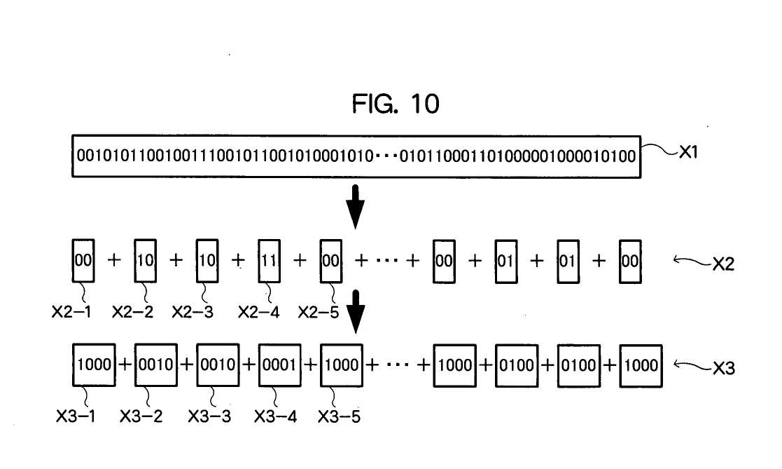

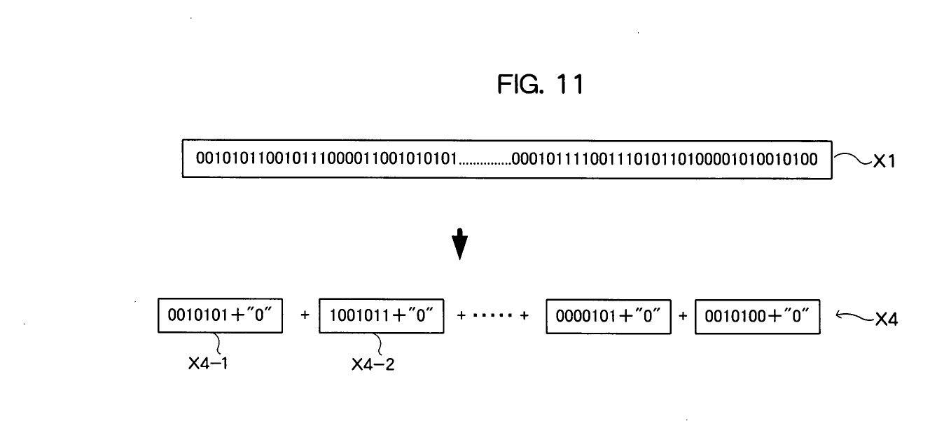

The configuration and the function of the optical receiver 20 will now be described. FIG. 9 is a functional block diagram showing the functional blocks of the optical receiver 20 of this embodiment. As is shown in the drawing, the optical receiver 20 includes a CPU 220, a storage 222, and a data acquiring section 224 in the data processing section 22. It also includes a synchronous circuit 240, a scramble data stream specifying section 242, a bit appending information specifying section 244, a scramble data stream storage 246, and an appended bit removal section 250 in the demodulating section 24. It further includes optical filters 260, light receiving elements 262, and equivalent circuits 264 in the light receiving section 26.

The function of each section included in the data processing section 22 will be described first.

The CPU 220 is a processing unit for executing a program stored in the storage 222, and it not only controls the respective sections in the light receiver 20, but also performs processing on transmission data. The storage 222 stores a program to perform this embodiment. Also, the storage 222 operates as a work memory for the CPU 220.

The data acquiring section 224 acquires transmission data as reception data from the demodulating section 24. The data acquiring section 224 then performs specific communication processing under the control of the CPU 220.

The function of each section included in the light receiving section 26 will now be described.

Each optical filter 260 is a filter that allows only light having a particular wavelength to pass through. It is set to pass visible light having a wavelength used in this visible light communications system 1. The wavelength may be variable. By allowing only a specific wavelength to pass through in this manner, light of only a particular color can be received at the light receiving elements 262.

The light receiving elements 262 are, for example, light sensors, and receive light having passed through the corresponding optical filters 260 at a resolution time at or higher than the blinking speed of the light emitting elements 160. Each light receiving element 262 then converts light thus received into an electrical signal, which is outputted to the corresponding equivalent circuit 264.

Each equivalent circuit 264 converts the frequency of the electrical signal outputted from the corresponding light receiving element 262 to a frequency to be handled in the demodulating section 24. The equivalent circuit 264 then outputs the converted electrical signal to the synchronous circuit 240.

The synchronous circuit 240 starts to receive the transmission data at timing specified in the synchronous header included in the transmission data. The synchronous circuit 240 then outputs the bit stream included in the communication payload among the received transmission data to an EXOR unit 248.

The scramble data stream specifying section 242 acquires the scramble information that specifies the scramble data stream used in the exclusive-OR operation performed in the EXOR unit 146 in the optical transmitter 10 from the light received at the light receiving elements 262. To be more concrete, the scramble data stream specifying section 242 reads out the scramble information from the transmission data received at the synchronous circuit 240 and outputs the scramble information to the scramble data stream storage 246.

The scramble data stream storage 246 stores at least the scramble data streams stored in the scramble data stream storage 148. The scramble data stream storage 246 chooses the scramble data stream specified by the scramble information inputted from the scramble data stream specifying section 242 among the scramble data streams stored therein, and outputs the scramble data stream thus chosen to the EXOR unit 248.

The bit appending information specifying section 244 reads out the bit appending information from the transmission data received at the synchronous circuit 240, and outputs this information to the appended bit removal section 250.

The EXOR unit 248 performs an inverse operation of the exclusive-OR operation performed in the EXOR unit 146. In the case of the exclusive-OR operation, the inverse operation is the processing to again compute using the same operation bit stream as the operation bit stream used on the bit stream in the first exclusive-OR operation. Herein, the EXOR unit 248 performs the exclusive-OR operation using the scramble data stream inputted from the scramble data stream storage 246 on the bit stream outputted from the synchronous circuit 240.

By performing the exclusive-OR operation in the EXOR unit 248 in this manner, the resulting output is the same bit stream as the output bit stream from the mark ratio control section 144 in the optical transmitter 10. In short, the output bit stream from the mark ratio control section 144 in the optical transmitter 10 is regenerated. This output bit stream is the one generated by appending a redundant bit to the transmission bit stream in the mark ratio control section 144. Hence, upon input of the bit stream outputted from the EXOR unit 248, the appended bit removal section 250 removes the appended redundant bit from the bit stream outputted form the EXOR unit 248 on the basis of the bit appending information inputted from the bit appending information specifying section 244. The output from the appended bit removal section 250 is thus restored to the original transmission data. The appended bit removal section 250 then outputs this transmission data to the data acquiring section 224.

As has been described, according to the invention, it is possible to perform fine-tuned adjustment of the luminance of the light emitting elements by the mark ratio control while suppressing an increase of the redundancy of the bit stream. Also, the operation bit stream to be handled for the transmission bit stream to have an arbitrary mark ratio can be identified by its mark ratio alone. Hence, an operation can be performed for the transmission bit stream to have an arbitrary mark ratio without the need to handle the operation bit stream for each bit alignment in the transmission bit stream. An exclusive-OR operation can be used as this operation.

Further, because an operation can be performed on the transmission bit stream for each specific length, the mark ratio can be controlled for each specific length. It is thus possible to suppress a local variation of the mark ratio after the operation.

Also, because the mark ratio of the transmission bit stream is the value corresponding to the target mark ratio, even when there is a limit for a quantity of change of the mark ratio by the operation, it is possible to perform the operation on the transmission bit stream so that the bit stream has the target mark ratio in a more reliable manner. Also, the optical receiver is able to acquire the operation bit stream according to the operation bit stream specifying information. Also, both the optical transmitter and the optical receiver are able to perform an operation or an inverse operation on the transmission bit stream or the bit stream to be received using the operation bit stream chosen among the previously stored operation bit streams.

Further, because fine-tuned adjustment of the luminance of the light emitting elements is enabled in response to a quantity of light sensed by the light sensor, the luminance of the light emitting elements as illumination light can be changed in response to a quantity of light sensed by the light sensor. It is thus possible to cancel out a variation of the illumination light.

Furthermore, because the luminance of the light emitting elements can be changed arbitrarily and maintained, the user who uses the illumination is allowed to fluctuate (increase or decrease) an output of the light emitting elements as illumination light while performing communication continuously.

While there have been described what are at present considered to be preferred embodiments of the invention, it will be understood that various modifications may be made thereto, and it is intended that the appended claims cover all such modifications as fall within the true sprint and scope of the invention.

Further, the disclosure of Japanese Patent Application No. 2005-84548 filed on Mar. 23, 2005, including specification, claims, drawings, and abstract is incorporated herein by reference in its entirety.

What is claimed is:

1. An optical transmitter, comprising:
a light emitting section that emits visible light on which is superimposed an input transmission bit stream by varying luminance according to the transmission bit stream;
a storage that stores plural operation bit streams each having a different mark ratio;
a light-control bit stream generating section that generates a light-control bit stream to which the mark ratio of the transmission bit stream is changed by performing a reversible bit operation on the transmission bit stream using one of the operation bit streams stored in the storage; and
a control section that controls light emission of the light emitting section according to the light-control bit stream generated in the light-control bit stream generating section.

2. The optical transmitter according to claim 1, wherein:
the storage stores an operation bit stream having a mark ratio c computed by:
c=(a−b)/(2a−1)
where a is a mark ratio of the transmission bit stream and b is a mark ratio of the light-control bit stream.

3. The optical transmitter according to claim 1, further comprising:
a mark ratio fluctuating section that fluctuates the mark ratio of the transmission bit stream which is not changed by the bit operation in the light-control bit stream generating section, in advance.

4. The optical transmitter according to claim 1, wherein:
the light-control bit stream generating section performs an exclusive-OR operation on the transmission bit stream.

5. The optical transmitter according to claim 1, further comprising:
a light receiving section that receives ambient light; and
an operation bit stream choosing section that chooses the operation bit stream having a mark ratio that cancels out a variation of the ambient light in response to an output of the light receiving section from the storage.

6. An optical receiver, comprising:
a storage that stores plural operation bit streams each having a different mark ratio;
a light receiving section that receives visible light whose luminance varies in response to a light-control bit stream to which the mark ratio of a data bit stream is changed by performing a reversible bit operation on the data bit stream;
a light-control bit stream acquiring section that acquires the light-control bit stream from the visible light received at the light receiving section;
a specifying information acquiring section that acquires an operation bit stream specifying information that specifies the operation bit stream used in the reversible bit operation from the visible light received at the light receiving section; and
a data bit stream regenerating section that regenerates the data bit stream by performing the reversible bit operation on the light-control bit stream using the chosen operation bit stream that is chosen from the storage according to the operation bit stream specifying information acquired by the specifying information acquiring section.
